(19) United States
(12) Patent Application Publication
(10) Pub. No.: US 2025/0196244 A1
(43) Pub. Date: Jun. 19, 2025

(54) METHOD AND LASER ARRANGEMENT FOR ELECTRICALLY CONTACTING TERMINAL FACES OF TWO SUBSTRATES

(71) Applicant: Pac Tech – Packaging Technologies GmbH, Nauen (DE)

(72) Inventors: Matthias Fettke, Berlin (DE); Andrej Kolbasow, Paulinenaue (DE); Thorsten Krause, Hoppegarten (DE); Svetlana Milz, Berlin (DE)

(21) Appl. No.: 18/981,554

(22) Filed: Dec. 15, 2024

(30) Foreign Application Priority Data
Dec. 14, 2023 (DE) 10 2023 135 169.9

(51) Int. Cl. B23K 1/005

(52) U.S. Cl. CPC B23K 1/0056

(57) ABSTRACT

A method for electrically contacting terminal faces of two substrates, the first substrate being positioned against the terminal faces of the second substrate, and a first laser radiation being applied to at least one of the substrates on the rear side in a first application phase, and a second laser radiation being applied to at least one of the substrates in a second application phase and a solder material arranged between the substrates being fused to establish an electrical contact between the terminal faces of the substrates, and the application in the first application phase being carried out with a first laser radiation, which has a wavelength that differs from the second laser radiation, and the switch from the first application phase to the second application phase being controlled by a control device A laser arrangement for applying laser energy to at least one substrate is proposed.

This application claims the benefit of German Patent Application No. 10 2023 135 169.9 filed on Dec. 14, 2023, the disclosure of which is incorporated herein by reference.

### TECHNICAL FIELD

The present invention relates to a method for electrically contacting terminal faces of two substrates. In addition, the present invention relates to a laser arrangement for applying laser energy to at least one substrate.

### BACKGROUND

Different methods for connecting or contacting terminal faces of two substrates, said terminal faces being arranged in an overlapping position, in which methods laser energy is used to generate the heat required for the connection in the area of the contact pairs formed from the terminal faces, are already known. For example, a method or an apparatus for thermally connecting terminal faces of two substrates is known, in which an optical fiber is used to introduce the laser energy into the contact pairs of the terminal faces, the cross-section of said optical fiber being dimensioned such that a simultaneous application of the laser radiation emitted from the end cross-section of the optical fiber to all contact pairs is possible. However, such methods do not allow any targeted application of laser radiation to individual contact pairs. Furthermore, with this method, the terminal faces of the substrates are in contact with each other without any additional compressive load, being secured in their relative position only by the dead weight of the upper substrate. Further, it is known that for thermally connecting terminal faces of two substrates, an application of laser radiation to a substrate on the rear side can be carried out via a transparent pressure plate, with which the terminal faces of the substrates are brought into contact with each other. A transparent glass plate is used as the pressure plate in this context.

Further, methods for directly mounting semiconductor chips on carrier substrates are known from the general prior art. For example, there are methods, in which the semiconductor chip is attached directly to the carrier substrate or to a printed circuit board with its terminal faces facing toward the carrier substrate and with the solder material previously applied to the terminal faces of the chip. During reflow soldering, the solder material coating is fused again in a soldering oven and is bonded with the terminal faces of the carrier substrate. Such methods are very complex, both in terms of their operations and in relation to the apparatuses required for them.

Further, it is known to connect the terminal contacts of two substrates by dispensing the solder material onto a solderable terminal contact of one of the substrates as a spherical solder material by means of a solder ball feeder of a laser soldering system and fusing it at least partially by means of a laser device in such a way that a material-bonded connection can be formed between the terminal contacts of the substrates. Alternatively, a solder material located on a terminal contact can be at least partially fused by heating one of the substrates in order to form a material-bonded connection between the terminal contacts of the substrates after the first substrate has been applied onto the second substrate. However, applying thermal energy onto the surface of a substrate can cause undesirable burning of the substrate, especially in the case of temperature-sensitive substrates. Only a small proportion of the laser radiation can be used to heat the solder material in dependency of the absorption capacity of the solder material or the substrate in generic methods, while a considerable proportion of the radiation is reflected by the solder material or the substrate without contributing to its heating. This causes considerable energy losses in practice, so that the amount of energy required to fuse the solder material increases significantly.

The object of the present invention is therefore to propose a method and a laser arrangement that allow two substrates to be reliably connected by fusing a solder material with low energy consumption. Furthermore, the contacting of the terminal faces of the substrates should be improved and damage to the substrates to be connected should be avoided.

The method for electrically contacting terminal faces of two substrates according to the invention, wherein the first substrate with its terminal faces facing toward the second substrate is electrically and mechanically connected to the terminal faces of the second substrate, can be divided into at least three phases, namely a positioning phase, a first application phase and a second application phase. In the positioning phase, the first substrate is positioned with its terminal faces relative to the terminal faces of the second substrate. The terminal faces of the first and second substrates can thus be arranged in an overlapping position for connecting or contacting the first and second substrates. In the first application phase, a first laser radiation is applied to at least one of the substrates, namely the first or the second substrate, on the rear side using a first laser device. In the context of the invention, “rear side” relates to the rear side of a substrate, which corresponds to the side of the substrate facing away from the other substrate. In other words, this means that the rear side of the first substrate is the side of the substrate facing away from the second substrate and the rear side of the second substrate is the side of the substrate facing away from the first substrate. The terminal faces of the substrate are arranged on the front side of the substrate opposite the rear side, with a solder material arranged between the terminal faces of the first substrate and the second substrate. Although the solder material as well as the substrates, in particular the substrate to which the laser radiation is applied using the first laser device, are heated by the application of a first laser radiation to one of the substrates using the first laser device in the first application phase, the solder material is not yet fused. The heating of the substrates and of the solder material to a higher temperature level can increase the absorption capacity of the substrates and of the solder material. This results in the advantageous effect that, following a switch to the second application phase, in which a second laser radiation is applied to at least one of the substrates using a second laser device, only the additional amount of energy that is required to heat the solder material to a fusing temperature starting from the temperature level reached in the first application phase, must be introduced, wherein the increased absorption capacity of the substrates and of the solder material after the first application phase reduces the proportion of reflection of the laser radiation, thereby increasing the effectiveness of the application of the second laser radiation. In the second application phase, the solder material arranged between the substrates is fused at least to such an extent that an electrical contact is established between the terminal faces of the first substrate and of the second substrate, said terminal faces facing each other. Preferably, the first substrate is also mechanically fixed on the second substrate in addition to establishing an electrical contact between the terminal faces facing each other. It can preferably be provided that the first substrate, with its terminal faces facing toward the second substrate, is electrically and mechanically connected directly to the terminal faces of the second substrate by fixing the terminal faces of the first substrate directly on the second substrate with the solder material previously applied to the terminal faces of the first substrate.

In the context of the invention, the term “solder material” also relates to copper pads for Cu—Cu hybrid bonding, sintering pastes and/or copper pillars in addition to solderable, in particular soft-solderable, metallic compounds, which, for example, are used in the form of solder paste or solder balls. The term “sintering paste” relates to a suspension, wherein the suspension comprises particles of at least one soft-solderable and conductive material and a solvent.

In the context of the invention, it has been recognized that, in addition to the division of the method according to the invention for electrically contacting terminal faces of two substrates into a positioning phase, a first application phase and a second application phase, it is further advantageous that in the first application phase the application is carried out with a first laser radiation, which has a wavelength that differs from the second laser radiation. The wavelength of the respective laser radiation can thus be adapted to the requirements in the first and/or second application phase, as it has been recognized that efficient preheating of the connection partners can be achieved by the application of a first laser radiation having a first wavelength, while efficient fusing of the solder material can be achieved by the application of a second laser radiation, having a second wavelength that differs from the first wavelength, to the connection partners. This offers the advantage that gentle heating with a first laser radiation that is easily absorbed by a multiplicity of materials can take place in the first application phase and that a second laser radiation, which induces a greater deep heating effect in the material of the connection partners, in particular in the solder material, is used only in the second application phase. As a result, thermal damage, in particular during the first application phase, can be prevented. Furthermore, the required laser power of the second laser device can be designed to be lower from the outset compared to generic laser devices due to the preheating, which reduces the system costs on the one hand and also allows the laser arrangement used in the method to be miniaturized on the other hand. The first laser radiation can preferably have a shorter wavelength than the second laser radiation. For example, the first laser radiation can be in an ultraviolet wavelength range in the first application phase and the second laser radiation can be in a near-infrared wavelength range in the second application phase.

Furthermore, it is conceivable that a lower laser energy input is required with the first laser device during the first application phase than with the second laser device during the second application phase. It is further conceivable that the second laser device for fusing the solder material can have a higher power than the first laser device. Due to the increased absorption capacity of the connection partners in the context of the first application phase, the power of the second laser device can be considerably reduced compared to generic methods with only one application phase. As a result, the second laser device can be controlled more precisely and thermal damage to the substrates can be prevented. Due to the lower laser energy input, preferably into the solder material and/or into the first substrate, the second laser device can have a significantly lower laser power than would be necessary without the use of a first laser device in a first application phase. However, as the power of a laser source can generally be controlled more precisely in a lower power range than in an upper power range, more precise control of the second laser device is possible as a result. On the other hand, thermal damage, which occurs in particular at high laser power, can be prevented. In particular, the required laser power of the second laser device can also be designed to be lower from the outset, which, on the one hand, allows a reduction in system costs and, on the other hand, also allows miniaturization of the laser arrangement used in method.

In the context of the invention, the fact that the switch from the first application phase to the second application phase is controlled using a control device in dependency of the duration of the first application phase, in dependency of the laser energy introduced into one of the substrates, in dependency of the temperature of one of the substrates and/or in dependency of the temperature of the solder material has been recognized to be advantageous. In other words, the control device is configured to activate the second laser device on the basis of different measured values or sensor data and thus to trigger the transition from the first application phase to the second application phase.

The control device can control the switch from the first application phase to the second application phase in dependency of the duration of the first application phase. This means that, if a first laser radiation has been applied to one of the substrates for a sufficient period of time using the first laser device, the switch from the first application phase to the second application phase is triggered by the control device. This is because the laser energy input can be determined on the basis of the duration of the application and on the laser power of the first laser device when assuming a constant laser power throughout the entire first application phase. If a sufficient laser energy into the connection partners, namely the first substrate, the second substrate and the solder material has taken place, the switch from the first application phase to the second application phase can be triggered by the control device.

Alternatively or additionally, the control device can control the switch from the first application phase to the second application phase in dependency of the laser energy introduced into one of the substrates and/or into the solder material. Compared to the control based solely on the duration of the first application phase, the control in dependency of the laser energy introduced offers the advantage that a control or variation of the laser power during the first application phase can also be taken into account. It has been recognized in this context that recording the laser power at any time during the first application phase allows precise calculation of the laser energy input into the connection partners, even if the laser power varies during the first application phase.

Further alternatively or additionally, the switch from the first application phase to the second application phase can be controlled using the control device in dependency of the temperature of one of the substrates and/or in dependency of the temperature of the solder material. The temperature of one of the connection partners can be monitored at least at regular intervals or continuously for this purpose. When the temperature of the connection partners is sufficient and the absorption capacity of the bonding partners has thus increased sufficiently, the switch from the first application phase to the second application phase can take place. Preferably, the temperature of the first substrate and/or the solder material is detected and the switch from the first application phase to the second application phase is controlled on the basis of their temperature values. It is also conceivable that the temperature of one of the substrates is measured and the temperature of the solder material can be determined taking into account the structure and materials of the substrates.

In the context of the invention, the term “substrate” is understood to include all components that are provided with a conducting path structure and external terminal faces for establishing contact. For example, chips, printed circuit boards or carrier substrates can thus be substrates in the context of the invention. A preferred field of application of the method proposed here or field of use of the arrangement proposed here is in the flip-chip technology and also in the area of SMD (surface-mounted device) technology.

In the context of the invention, the term “connection partner” refers to the first substrate, the second substrate and the solder material.

The term “laser device” can be understood to be a laser emission device for the emission of laser radiation alone or also a laser emission device in combination with a radiation guiding device, by means of which the laser radiation is guided from the laser emission device to the connection partners. Devices having lenses and/or mirrors are known as radiation guiding devices.

As a result, the proposed method can be used very universally, as different substrates, including metallized chips, for example, can be connected to another substrate. The universal use of the method is essentially based on the fact that the two application phases can be adapted very precisely to the connection partners. Furthermore, this makes it possible to increase the energy efficiency of the method and to minimize damage to the connection partners. In particular, fractures of materials, such as those occurring when chips, which are regularly made of different materials, are heated in a generic manner, can be avoided. In this context, it has been recognized as advantageous if the chip is not heated step-by-step, but rather according to a gradient.

Further, it has been recognized in the context of the invention that the surroundings can also be heated in addition to the connection partners during the first application phase using the first laser device, whereby the contacting of the terminal faces of the first and second substrates, said terminal faces facing each other, is improved and simplified during the second application phase. Further, it has been recognized that an adhesive can be cured using the first and/or second laser device. In particular, the adhesive can be cured by the energy input and the heating of the adhesive occurring as a result. By way of example but not exclusively, an epoxy compound, a dry film, a bis-benzocyclobutene (BCB) compound, a polyimide compound and/or a UV-curing compound can be used as an adhesive.

Advantageous embodiments of the invention are the subject matter of the dependent claims. Furthermore, all combinations of at least two of the features disclosed in the description, the claims and/or the figures are within the context of the invention. It is understood that all features and embodiments disclosed with regard to the method also relate in an equivalent, albeit not identical, manner to the laser arrangement according to the invention. In this context, it is particularly understood that linguistically common conversions and/or an analogous replacement of respective terms in the context of customary linguistic practice, in particular the use of synonyms supported by generally recognized linguistic literature, are covered by the present disclosure without being explicitly mentioned in their respective formulation.

The temperature of a connection partner can be measured contactlessly in an advantageous manner. A temperature sensor can be used to measure the radiation temperature of at least one of the substrates and/or of the solder material at least during the first application phase. The switch from the first application phase to the second application phase using the control device can then be controlled in dependency of the radiation temperature of one of the substrates and/or in dependency of the radiation temperature of the solder material. Advantageously, the temperature sensor can be realized as an infrared pyrometer. Such infrared pyrometers can measure with high precision and speed and, thanks to their compact construction, are suitable for applications with limited installation space. They are also relatively lightweight and can be positioned extremely flexibly due to their compact design. For example, an infrared pyrometer can be arranged within a joining tool of a laser arrangement for electrically contacting terminal faces of two substrates. An infrared pyrometer thus offers a multiplicity of advantages, in particular compared to known infrared cameras for detecting temperature, which are extremely large and heavy compared to an infrared pyrometer. In particular, the rapid detecting of temperature, which advantageously takes place within less than 1 ms, further preferably within less than 0.3 ms, is a significant advantage compared to the relatively slow detecting of temperature by an infrared camera, which is usually in the range of 25 ms. Preferably, the radiation temperature of the first substrate and/or of the solder material can be measured by means of a temperature sensor at least during the first application phase, and the switch from the first application phase to the second application phase can be controlled using the control device in dependency of the radiation temperature of the first substrate and/or in dependency of the radiation temperature of the solder material.

In the second application phase, the application using the second laser device can take place in addition to the application using the first laser device. The laser radiation is thus simultaneously applied to the connection partners by the first and the second laser device in the second application phase. The fact that the application using the first laser device is maintained allows the second laser device to be operated at an even lower power.

If the radiation temperature of at least the first substrate, the second substrate and/or the solder material is measured by means of a temperature sensor during the first application phase, the radiation temperature of at least the first substrate, the second substrate and/or the solder material can also be measured by means of the temperature sensor during the second application phase. The termination of the second application phase can then take place in dependency of the measured radiation temperature during the second application phase of at least the first substrate, the second substrate and/or the solder material. The method can thus be performed with a minimum of equipment and control effort.

The switching temperature at which the switch from the first application phase to the second application phase is triggered can be selected in dependency of the properties of the substrates to be contacted and/or of the solder material. The material-specific absorption capacity of the substrates and/or of the solder material, which changes with the temperature of the material, can thus be taken into account in each case for the specification of the switching temperature when defining the switching temperature.

The first laser device can be switched on in a standby mode being clocked for a defined duty cycle and can be switched to an operating mode by means of the control device in dependency of the presence temperature of at least one substrate measured by means of the temperature sensor. In the context of the invention, “standby mode” refers to a standby mode of the first laser device, in which the actual function of the laser device, namely the emission of laser radiation, is temporarily deactivated, but can be activated at any time and without preparations or longer waiting times. In the context of the invention, the “presence temperature” of a substrate is a temperature or a temperature change that occurs as soon as a substrate is placed in the measuring range of the temperature sensor. It is thus possible to use the temperature sensor not only to trigger the switch between the first application phase and the second application phase and, if necessary, also to terminate the second application phase, but to also use the temperature sensor to detect at least one substrate, as the measurement of a temperature of the substrate requires the presence of the substrate. The temperature sensor thus allows the method to be triggered as soon as a substrate is in the measuring range of the temperature sensor. In particular, the method can be triggered if a temperature of the first substrate can be measured by means of the temperature sensor during a duty cycle of the first laser device that is repeated in a clocked manner, during which the first laser device is in a standby mode. This is because the temperature of the first substrate can only be measured if the first substrate is present, so that a temperature value determined by the temperature sensor or a temperature change determined by the temperature sensor indicates the presence of the first substrate.

According to a preferred embodiment, the first laser radiation can be applied to the first substrate on the rear side using the first laser device in the first application phase, and the second laser radiation can in turn be applied to the first substrate on the rear side using the second laser device in a second application phase. This means that both the first laser radiation and the second laser radiation strike the first substrate on the rear side, whereby the apparatus for carrying out the method can be compact.

According to a further preferred embodiment, the first laser radiation can be applied to the first substrate on the rear side and to the second substrate on the front side using the first laser device in the first application phase. The second laser radiation can subsequently be applied to the first substrate on the rear side using the second laser device in the second application phase. In the first application phase, the first laser radiation is then applied to both the first substrate and the second substrate. This can be done in such a way that, for example, the first substrate is smaller than the second substrate and the focus of the laser radiation transverse to the application direction is larger than the first substrate, whereby the first laser radiation not only strikes the first substrate, but also strikes the second substrate. Furthermore, this has the positive effect that the surroundings of the connection partners, the surroundings of the first substrate in particular, can be preheated during the first application phase. In the second application phase, the focus of the second laser beam can then be oriented in such a way that the second laser radiation only strikes the first substrate and that, consequently, energy is only introduced into the first substrate.

According to another embodiment, the first laser radiation can be applied to the second substrate on the rear side using the first laser device in the first application phase and the second laser radiation can be applied to the first substrate using the second laser device in the second application phase. This offers the advantage that no elaborate deflection device or radiation guiding device is required, because the laser radiation can, for example, be applied to the second substrate from below in the first application phase and to the first substrate from above in the second application phase. The application of the first laser radiation can thus also be realized in a simple way both in the first application phase and in the second application phase.

The activation of a process gas can take place or can be supported using at least the first laser device in the first application phase. In particular, a process gas can be heated by at least the first laser radiation. By way of example and but by no means exclusively, argon, oxygen, nitrogen, hydrogen or helium can be used as a process gas. Process gas can be used to create low-reaction surroundings and/or reducing surroundings. Process gas can also be used to expel reactive gases after and/or before a process step.

In a second aspect, the invention relates to a laser arrangement for applying laser energy to at least one substrate, the laser arrangement comprising:
at least one first laser device, which emits a first laser radiation, and
at least one second laser device, the second laser device emitting a laser radiation, which has a wavelength that differs from the first laser radiation, and
a control device, which is configured to activate the second laser device, the control device having a temperature sensor and/or a time sensor.

A first laser radiation can then be applied to at least one of the substrates on the rear side using the first laser device in the first application phase, while a second laser radiation can be applied to at least one of the substrates using the second laser device in the second application phase in order to establish an electrical contact between the terminal faces of the first substrate and the second substrate, said terminal faces facing each other. As already described with regard to the method, the absorption capacity of the connection partners can be increased due to the preheating of the connection partners, in particular of the substrate to which the first laser radiation is applied in the first application phase, which is why the power of the laser device used in the second application phase can be reduced compared to generic devices and methods having only one application phase. The first laser device can already preheat the substrates and the solder material, but cannot yet fuse the solder material. The establishing of an electrical contact between the terminal faces of the first substrate and of the second substrate, said terminal faces facing each other, takes place only in the second application phase during the application of laser radiation to at least one of the substrates using the second laser device, wherein the solder material is fused to establish contact. The control device can activate the second laser device, in other words, can control the switch from the first application phase to the second application phase, by means of the temperature sensor and/or the time sensor. The switch from the first application phase to the second application phase in dependency of the temperature of one of the substrates and/or in dependency of the temperature of the solder material can be controlled by means of the temperature sensor. The control device can activate the second laser device in dependency of the laser energy introduced into one of the substrates and/or in dependency of the duration of the first application phase by means of the time sensor, and can thus control the switch from the first application phase to the second application phase.

It is conceivable that the laser arrangement comprises at least one further laser device, the further laser device being able to emit a further laser radiation, which has a wavelength that differs from the first and/or second laser radiation. The laser arrangement can preferably have a third laser device, the third laser device being able to emit a third laser radiation and the third laser radiation having a wavelength that differs from the first and/or second laser radiation. The third laser radiation can be applied to the connection partners in a third application phase. The laser arrangement can have a fourth laser device in addition to the third laser device, the fourth laser device being able to emit a fourth laser radiation and the fourth laser radiation having a wavelength that differs from the first, from the second and/or from the third laser radiation. The laser radiation can be applied to the connection partners in a fourth application phase. The laser arrangement can comprise any number of additional laser devices.

The first laser device can have an ultraviolet laser (UV laser) and can thus emit UV laser radiation. The second laser device can have a near-infrared laser (NIR laser) and can thus emit NIR laser radiation. It is known that an ultraviolet laser emits laser radiation in a wavelength range from 200 nm to 400 nm. Further, it is known that a near-infrared laser (NIR) emits laser radiation in a wavelength range from 785 nm to 1550 nm. In the context of the invention, it has been recognized that an ultraviolet laser and its emitted laser radiation are particularly suitable for preheating the connection partners. By contrast, a near-infrared laser, whose emitted laser radiation is in a wavelength range that differs from the UV laser, is advantageously suitable for fusing the solder material for establishing contact between the terminal faces in the second application phase.

It is also conceivable that the first laser device has a diode laser as a source of radiation and the second laser device has a pulse laser as a source of radiation, so that the particular advantage resulting from the performance of the method according to the invention is already taken into account when selecting the laser devices, namely that a source of radiation, for example, with relatively low power, is used for the first laser device, which must only be sufficient to bring the connection partners to a temperature level with increased absorption capacity, and the second laser device is realized as a “power laser” compared to the first laser device.

The laser arrangement can comprise a joining tool for positioning and joining the first substrate on the second substrate. A beam channel for a beam path of the first laser radiation and/or for a beam path of the second laser radiation can be realized within the joining tool. The first substrate can be positioned with its terminal faces against the terminal faces of the second substrate by means of the joining tool. The joining tool can have a holder for removable fixation of the first substrate to the joining tool for this purpose. The first substrate can be held and positioned relative to the second substrate by means of the holder and, in particular, can be brought into an overlapping position with the second substrate. Furthermore, it is conceivable that pressure can be applied to the first substrate by the joining tool in order to improve the connection between the first substrate and the second substrate. As a beam channel for a beam path of the first laser radiation and/or for a beam path of the second laser radiation is realized within the joining tool, the application of laser radiation to at least one substrate can be effected in a simple way by means of the joining tool. Designing of the apparatus can thus be less complex, and the laser radiation, which is applied via the beam channel of the joining tool, can be applied directly to the rear side of the substrate fixed to the joining tool. Therefore, it is not necessary to take into account another laser device or another beam channel realized separately from the joining tool in the surroundings of the connection partners, whereby the joining tool can be moved significantly more easily, as no collisions with another beam channel need to be taken into account. In other words, the joining tool thus has significantly more space available, whereby travel distances and deviations in position can be minimized.

The temperature sensor for detecting the radiation temperature can be arranged in a beam path of a reflection radiation of the first substrate, the second substrate and/or the solder material. The temperature sensor can be realized as an infrared sensor, preferably as a pyroelectric infrared sensor. Contactless measurement of the temperature of the connection partner of which the reflection radiation is to be captured is thus possible. It is conceivable that the reflection beam resulting from application of the laser radiation anyways is used for temperature measurement by means of the infrared sensor.

The temperature sensor can be arranged within the laser arrangement in such a way that the beam path of the reflection radiation intended for temperature measurement and the beam path of the first laser radiation and the beam path of the second laser radiation run simultaneously in the beam channel, at least in sections. This makes it possible to advantageously shield all the beam paths from the surroundings by realizing merely one beam channel. Preferably, the beam channel, in which the beam path of the reflection radiation and the beam path of the first laser radiation and the beam path of the second laser radiation can run simultaneously, at least in sections, is realized within a joining tool. The infrared sensor can be arranged at the end of the beam channel within the joining tool spaced from the substrate. The end of the beam channel facing toward the substrate can be realized by the holder, which can be used to hold the first substrate. However, it is also conceivable that the beam path of the reflection radiation and the beam path of the first laser radiation run simultaneously in a common beam channel, at least in sections, while the beam path of the second laser radiation runs in a separate beam channel.

The laser arrangement can have a substrate support on which at least the rear side of one of the substrates can be fixed. The rear side of the second substrate can preferably be fixed to the substrate support. The positioning of the first substrate relative to the second substrate can be simplified by the fixation of the rear side of one of the substrates on the substrate support. Preferably, the first substrate or the second substrate is held in a form-fit manner on the substrate holder so that the underside of the substrate being held rests against the substrate holder. Furthermore, it is conceivable that the substrate to be held is held on the substrate holder by generating a holding force. A negative pressure can be applied to the substrate resting against the substrate holder in order to generate the holding force, The substrate holder therefore allows the substrate to be positioned while being held.

An optical window having an optically transparent window body for an unimpeded passage of a laser radiation and/or reflection radiation into and/or out of at least one substrate can be introduced into the substrate support. In the context of the invention, the term “optical window” refers to optically transparent plates that are typically designed in such a way that they offer maximum transmission of optical radiation, in the present case preferably laser radiation, in a certain wavelength range and simultaneously reduce reflection and absorption. Furthermore, an optical window can act as a thermal insulator so that the greatest possible amount of heat can be transferred through the optical window. The optical window can be arranged in a beam path of one of the laser radiations and/or in a beam path of the reflection radiation that can be captured by means of the temperature sensor. In other words, the first laser radiation, the second laser radiation and/or the reflection radiation can penetrate the optically transparent window body of the optical window. Additional laser radiation can be introduced into a substrate, in particular into the underside of the second substrate, by means of the optical window, and/or a reflection radiation can be reflected and captured through the optical window. As a result, it is possible to apply laser energy through the optical window via the underside of the second substrate, in particular during the first application phase. Further, the first substrate to be arranged on the second substrate can be positioned in a simple way without taking the second laser device into account, whereby the joining tool has significantly more space available above the joining partners due to the application of the second laser radiation from below. Travel distances that are necessary, for example, when changing or orienting the joining tool, the first laser device and/or the capturing device above the joining partners can therefore also be minimized, thus preventing deviations in position during the joining process and/or in the positioning phase.

The joining tool can have a holder having a negative pressure device for applying negative pressure to the first substrate, wherein the first substrate is able to be fixed to an opening of a pressure chamber of the negative pressure device. The first substrate is preferably able to be removably fixed to an opening of a pressure chamber of the negative pressure device, wherein the substrate can be removed by releasing the negative pressure. The fixation of the substrate to the joining tool by negative pressure allows the substrate to be held gently, in particular without deformation, on the joining tool and to be positioned relative to the second substrate. The negative pressure can be formed in a pressure chamber, at the opening of which the first substrate can be positioned, so that the negative pressure rests against the substrate and holds it on the holder. The pressure chamber can have at least one side wall, wherein the other walls closing the pressure chamber can be formed by an optical window and by the first substrate. This means that an optical window can be arranged opposite the opening of the pressure chamber at a distance from the second substrate. Advantageously, it is sufficient for positioning if only the side walls of the pressure chamber are brought to rest against the substrate, thereby in turn allowing the substrate to be held gently and preventing deformations, which can occur when an optical window is in direct contact with the substrate. Furthermore, it is thus possible to also fix three-dimensional substrates to the joining tool. It has proven to be particularly advantageous if the side walls of the holder come to rest against the rear side of the first substrate. This makes it possible for the laser radiation striking the first substrate through the holder to be focused on the first substrate and to rule out stressing or burning of the surfaces surrounding the substrate, for example, those of the second substrate. It is conceivable that the negative pressure device of the holder also generates the negative pressure with which the second substrate can be held on the substrate support. Installation space can thus be advantageously saved, as the substrate support and the holder jointly use a negative pressure device.

The beam channel, which extends within the joining tool at least in sections, can be arranged at least partially within the pressure chamber, and/or the pressure chamber can form at least one section of the beam channel. Preferably, the pressure chamber forms the last section of the beam channel, meaning the section of the beam channel that comes to rest against the substrate.

The laser arrangement can comprise a radiation guiding device, which has at least one mirror and/or a lens for guiding the laser radiation onto one of the substrates. In particular, if two laser radiations are to be guided through a single beam channel, the radiation guiding device can have at least one semi-transparent optical mirror. The laser radiation from one of the two laser devices can then penetrate the semi-transparent mirror so that the laser radiation strikes the rear side of the substrate, and the laser radiation from the other laser device is deflected by the semi-transparent mirror so that the beam path of the other laser radiation is also directed onto the rear side of the substrate.

It is understood that the aforementioned embodiments and examples that will be further explained below can be implemented not only individually, but also in any combination with each other, without departing from the scope of the present invention. It is also understood that the aforementioned embodiments and examples that will be further explained below relate to the method according to the invention in an equivalent or at least similar manner, without being mentioned separately for same.

Embodiments of the invention are schematically illustrated in the drawings and are explained in the following by way of example.

### BRIEF DESCRIPTION OF THE DRAWINGS

FIG. 1 is a first embodiment of a laser arrangement according to the invention;

FIG. 2 is a second embodiment of a laser arrangement according to the invention and

FIG. 3 is a third embodiment of a laser arrangement according to the invention.

### DETAILED DESCRIPTION

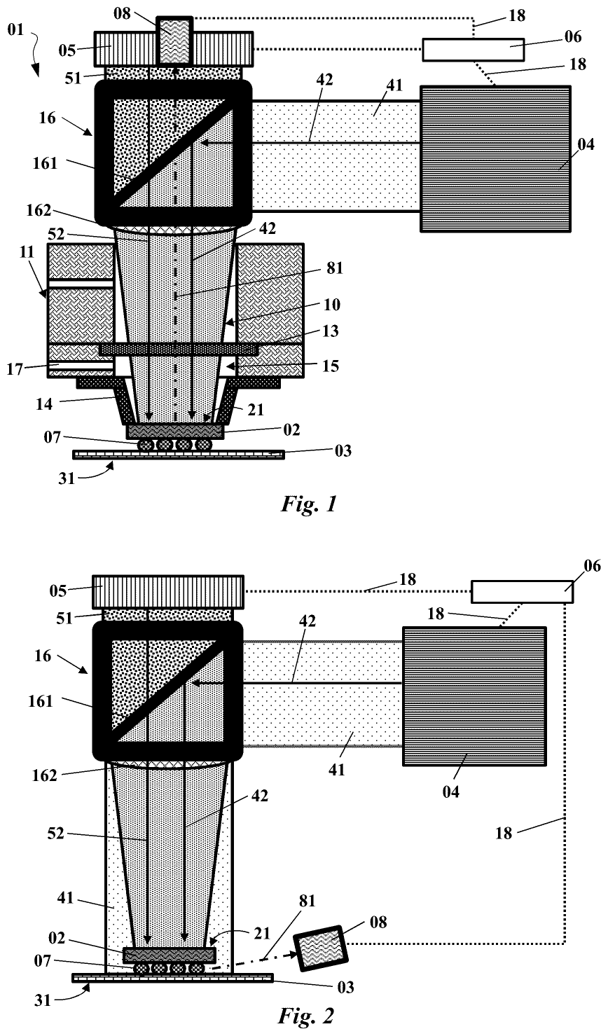

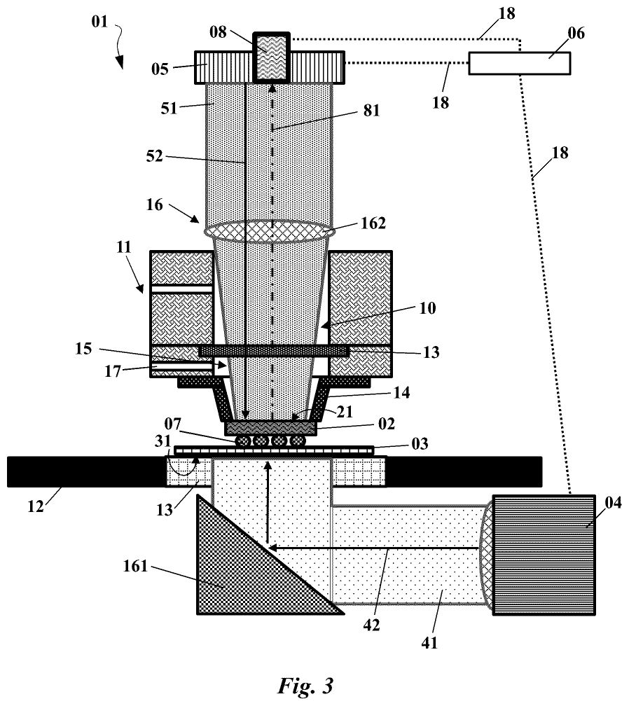

FIG. 1 shows an embodiment of the laser arrangement 01 according to the invention for applying laser energy to at least one of the substrates 02, 03, the laser arrangement 01 being suitable for carrying out the method according to the invention for electrically contacting the terminal faces of two substrates 02, 03. In the illustration shown in FIG. 1, the first substrate 02 is arranged above the second substrate 03 in an overlapping position with the second substrate 03 by means of the joining tool 11. The solder material 07 is arranged between the first substrate 02 and the second substrate 03. The solder material 07 is arranged on the terminal faces of the substrates 02, 03, the terminal faces each being formed on the front side of the substrates 02, 03. On the other hand, the rear side 31 of the second substrate 03 is facing away from the solder material 07 and can be positioned on a substrate support 12 not shown here. The rear side 21 of the first substrate 02 can be brought into contact with the holder 14 of the joining tool 11, as shown in FIGS. 1 and 3. Negative pressure can be applied to the first substrate 02 for fixation to the holder 14, said negative pressure being formed within the pressure chamber 15, which is connected to a negative pressure pump, not shown here, of the negative pressure device via the pressure line 17. It is evident that the pressure chamber 15 is formed by the optical window 13 and the side walls of the joining tool 11 or of the holder 14 of the joining tool, wherein the opening of the pressure chamber 15 is formed by the opening of the holder 14 and can be closed by the first substrate 02, so that negative pressure is also applied to the substrate 02 for fixation and positioning the same on the holder 14 when negative pressure is applied to the pressure chamber 15. Through the optical window 13, which is arranged within the beam channel 10 arranged in the joining tool 11, a first laser radiation 41, which is emitted by the first laser device 04, and a second laser radiation 51, which is emitted by the second laser device 05, can be applied to the rear side 21 of the first substrate 02. Thus, the first laser radiation 41 can be applied to the first substrate 02 during a first application phase and the second laser radiation 51 can be applied to the substrate 02 during the second application phase. It is also conceivable that the first laser radiation 41 and the second laser radiation 51 are applied to the substrate 02 in the second application phase. A control device 06 and a temperature sensor 08 are comprised in order to carry out a switch between the application phases or to activate the second laser device 05 and trigger an exposure to the second laser radiation 51. The temperature sensor 08 is arranged in the beam channel 10 in such a way that the temperature sensor 08 can capture the reflection radiation 81 reflected from the rear side 21 of the first substrate 02 and can transmit temperature measurements to the control device 06. The temperature sensor 08 and the control device 06 are connected via a data link 18 shown as a dotted line and serving to transmit the temperature measurements and/or to supply the temperature sensor with power. Further, the control device 06 can be connected to the first laser device 04 and the second laser device 05 via a data link 18 shown as a dotted line. Furthermore, the control device 06 can have a time sensor, not shown here, in addition to the temperature sensor 08. The control device 06 is configured to control the switch from the first application phase to the second application phase in dependency of the duration of the first application phase, in dependency of the laser energy introduced into the first substrate 02 or in dependency of the temperature of the first substrate 02. It is also conceivable that the control device 06 is configured to determine the temperature of the solder material 07 on the basis of the temperature of the first substrate 02, its reflection radiation, which the temperature sensor 08 receives, and the properties of the first substrate 02. Further, it is evident that the beam path 42 of the first laser beam 41 emitted by the first laser device 04 is deflected in the direction of the first substrate 02 by the semi-transparent mirror 161 of the radiation guiding device 16. By contrast, the beam path 52 of the second laser beam 51 emitted by the second laser device 05 extends through the semi-transparent mirror 161 of the radiation guiding device 16 in the direction of the first substrate 02 without being deflected. The radiation guiding device 16 also has a lens 162 serving to focus the laser radiations.

FIG. 2 shows a second embodiment of a laser arrangement 01 according to the invention, having a first laser device 04 and a second laser device 05. It is evident that the first laser radiation 41 emitted by the first laser device 04, which follows the beam path 42, is not only focused on the rear side 21 of the first substrate 02, but also applies radiation to the areas adjacent to the substrate 02. The first laser radiation 41 thus strikes not only the first substrate 02, but also the second substrate 03 and therefore preheats both the surroundings of the first substrate 02 and the second substrate 03. Further, in contrast to the first embodiment, the temperature sensor 08 is arranged in such a way that it captures reflection radiation 81 coming from the solder material 07 and can thus contactlessly measure the temperature of the solder material 07. The radiation guiding device 16, having a semi-transparent mirror 161, in turn redirects the first laser radiation 41 along the beam path 42 and focuses the second laser radiation 51, which has the beam path 52 and is emitted by the second laser device 05, onto the rear side 21 of the first substrate 02 by means of the lens 162. The radiation guiding device 16 can have a further lens, not visible here, in order to focus the first laser radiation 41 onto the connection partners and onto a defined area of the surroundings. This means that, with the laser arrangement 01 shown in FIG. 2, the first substrate 02 as well as the second substrate 03 and the surroundings of the first substrate 02 can be preheated by the first laser radiation 41 in a first application phase, and the second laser radiation 52 can be applied to the first substrate 02 in the second application phase, so that the solder material 07 fuses and an electrical contact is established between the terminal faces of the first substrate 02 and the second substrate 03, said terminal faces facing each other. The control device 06 can additionally have a time sensor in addition to the temperature sensor 08, so that the control device 06 can control the switch from the first application phase to the second application phase in dependency of the duration of the first application phase, in dependency of the laser energy introduced into one of the substrates 02, 03 or in dependency of the temperature of the solder material 07.

The embodiment of the laser arrangement 01 according to the invention shown in FIG. 3 largely corresponds to the embodiment shown in FIG. 1, but differs from it in that the first laser radiation 41 emitted by the first laser device 04 strikes the rear side 31 of the second substrate 03. For this purpose, the second substrate 03, in particular the rear side 31 of the second substrate 03, is positioned on the substrate support 12 in such a way that the rear side 31 of the substrate 03 comes to rest against the optical window 13 introduced into the substrate support 12. The beam path is directed through this optical window 13 by means of the mirror 161 of the radiation guiding device 16. According to FIG. 3, the radiation is applied to the first substrate 02 from above the connection partners in the second application phase. The first substrate 02 can be positioned relative to the second substrate 03 by the joining tool 11. The laser radiation 51 follows the beam path 52 through the lens 162 serving to focus and through the optical window 13 of the joining tool 11 onto the rear side 21 of the first substrate 02. Negative pressure can be applied to the pressure chamber 15 formed at the end of the joining tool 11 facing toward the first substrate 02 via the pressure line 17 in order to fix the first substrate 02 to the holder 14 of the joining tool 11. The second laser radiation 51 is guided through the beam channel 10 of the joining tool 11 after focusing in order to shield the second laser radiation 51. The control device 06 in turn serves to control the switch between the first application phase and the second application phase and can have a time sensor, not shown here, in addition to the temperature sensor 08 shown here. The temperature sensor 08 captures the reflection radiation 81, which is emitted from the rear side 21 of the first substrate 02. The temperature sensor 08 can be arranged on or in the area of the laser device 05. The control device 06 can control the switch from the first application phase to the second application phase in dependency of the duration of the first application phase, in dependency of the laser energy introduced into the second substrate 03 by the first laser device 04 or in dependency of the temperature of the first substrate 02. In contrast to FIG. 1, no elaborate radiation guiding device 161 is to be provided above the connection partners according to the embodiment shown in FIG. 3. Furthermore, the joining tool 11 has significantly more free space available when the joining tool 11 moves, as the first laser device 04 is arranged below the substrate support 12, and thus not in the movement area of the joining tool 11.

### LIST OF REFERENCE SYMBOLS

01 Laser arrangement

02 First substrate
21 Rear side of first substrate

03 Second substrate
31 Rear side of second substrate

04 First laser device
41 First laser radiation
42 Beam path of the first laser device

05 Second laser device
51 Second laser radiation
52 Beam path of the second laser device

06 Control device

07 Solder material

08 Temperature sensor
81 Reflection radiation

10 Beam channel

11 Joining tool

12 Substrate support

13 Optical window

14 Holder

15 Pressure chamber

16 Radiation guiding device
161 Mirror
162 Lens

17 Pressure line

18 Data link

1. A method for electrically contacting terminal faces of two substrates (02, 03), the first substrate (02) being electrically and mechanically connected to the terminal faces of the second substrate (03) with its terminal faces facing toward the second substrate (03), wherein - Positioning the first substrate (02) with its terminal faces against the terminal faces of the second substrate (03) and - Applying a first laser radiation (41) to at least one of the substrates (02, 03) on the rear side using a first laser device (04) in a first application phase and I Applying a second laser radiation (51) to at least one of the substrates (02, 03) using a second laser device (05) in a second application phase and a solder material (07) arranged between the substrates (02, 03) is fused at least to such an extent that an electrical contact is established between the terminal faces of the first substrate (02) and of the second substrate (03), said terminal faces facing each other, and in the first application phase the application is carried out with a first laser radiation, which has a wavelength that differs from the second laser radiation, the switch from the first application phase to the second application phase is controlled using a control device (06) in dependency of the duration of the first application phase, in dependency of the laser energy introduced into one of the substrates (02, 03), in dependency of the temperature of one of the substrates (02, 03) or in dependency of the temperature of the solder material (07).

2. The method according to claim 1, wherein the radiation temperature of at least one of the substrates (02, 03) or of the solder material (07) is measured at least during the first application phase by means of a temperature sensor (08), and the switch from the first application phase to the second application phase is controlled using the control device (06) in dependency of the radiation temperature of one of the substrates (02, 03) or in dependency of the radiation temperature of the solder material (07).

3. The method according to claim 1 wherein, in the second application phase, the application using the second laser device (05) takes place in addition to the application using the first laser device (04).

4. The method according to claim 2, wherein the radiation temperature of at least one of the substrates (02, 03) or of the solder material (07) is measured by means of the temperature sensor (08) during the second application phase and the termination of the second application phase takes place in dependency of the radiation temperature of at least one of the substrates (02, 03) or of the solder material (07).

5. The method according to claim 1, wherein the first laser device (04) is switched on in a standby mode being clocked for a defined duty cycle and is switched to an operating mode by means of the control device (06) in dependency of a presence temperature of at least one of the substrates (02, 03) measured by means of the temperature sensor (08).

6. The method according to claim 1, wherein the first laser radiation (41) is applied to the first substrate (02) on the rear side using the first laser device (04),
and the second laser radiation (51) is applied to the first substrate (02) on the rear side using the second laser device (05) in a second application phase.

7. The method according to claim 1, wherein the first laser radiation (41) is applied to the first substrate (02) on the rear side and to the second substrate (03) on the front side using the first laser device (04) in the first application phase,
and the second laser radiation (51) is applied to the first substrate (02) on the rear side using the second laser device (05) in the second application phase.

8. The method according to claim 1, wherein the first laser radiation (41) is applied to the second substrate (03) on the rear side using the first laser device (04) in the first application phase,
and the second laser radiation (51) is applied to the first substrate (02) using the second laser device (05) in the second application phase.

9. The method according to claim 1, wherein a process gas is activated at least in the first application phase.

10. A laser arrangement (01) for applying laser energy to at least one substrate (02, 03), the laser arrangement comprising:
at least one first laser device (04) and
at least one second laser device, the second laser device emitting a laser radiation which has a wavelength that differs from the first laser radiation, and
a control device (06), which is configured to activate the second laser device (05), the control device (06) having a temperature sensor (08) or a time sensor.

11. The laser arrangement according to claim 10,
wherein
the first laser device (04) has an ultraviolet laser and the second laser device (05) has a near-infrared laser.

12. The laser arrangement according to claim 10 further including a joining tool (11) for positioning and joining the first substrate (02) on the second substrate (03), a beam channel (10) for a beam path (42) of the first laser radiation (41) or for a beam path (52) of the second laser radiation (51) being realized within the joining tool (11).

13. The laser arrangement according to claim 10, wherein the temperature sensor (08) for detecting the radiation temperature is arranged in a beam path of a reflection radiation (81) of the first substrate (02), of the second substrate (03) or of the solder material (07) and is realized as an infrared sensor.

14. The laser arrangement according to claim 10, further including a substrate support (12) on which at least the rear side of one of the substrates (02, 03 is fixed.

15. The laser arrangement according to claim 14,
wherein
an optical window (13) having an optically transparent window body for an unimpeded passage of a laser radiation (41, 51) or reflection radiation (81) into or out of at least one substrate (02, 03) is introduced into the substrate support (12), the optical window (13) being arranged in a beam path (42, 52) of one of the laser radiations (41, 51) or in a beam path of the reflection radiation (81), which can be captured by means of the temperature sensor (08).

16. The laser arrangement according to claim 10, wherein the joining tool (11) has a holder (14) having a negative pressure device for applying negative pressure to the first substrate (02), the first substrate (02) being able to be fixed to an opening of a pressure chamber (15) of the negative pressure device.
